(19) United States
(12) Patent Application Publication
(10) Pub. No.: US 2025/0316450 A1
(43) Pub. Date: Oct. 9, 2025

(54) PLASMA-ENHANCED DEPOSITION REACTOR

(71) Applicants: UNIVERSITE GRENOBLE ALPES, Saint Martin D'Heres (FR); CENTRE NATIONAL DE LA RECHERCHE SCIENTIFIQUE, Paris (FR)

(72) Inventors: Marceline BONVALOT, Saint Ismier (FR); Thierry CHEVOLLEAU, Saint Egreve (FR); Moustapha JAFFAL, Grenoble (FR)

(21) Appl. No.: 18/866,416

(22) PCT Filed: May 15, 2023
(86) PCT No.: PCT/EP2023/062985

§ 371 Date: Nov. 15, 2024

(30) Foreign Application Priority Data
May 17, 2022 (FR) FR2204648

(51) Int. Cl. H01J 37/32; C23C 16/458; C23C 16/509

(52) U.S. Cl. CPC H01J 37/32091; C23C 16/4583; C23C 16/509; H01J 37/321; H01J 37/32357; H01J 2237/332

(57) ABSTRACT

A plasma-enhanced deposition reactor including a reaction chamber including a plate having an upper face for receiving a substrate, a gas precursor inlet in the chamber, a pumping module of the chamber, a power source configured to apply a radio frequency bias to the plate, wherein a lateral wall of the chamber is at least partially non-parallel to the upper face of the plate, and the upper face of the plate and the lateral wall are separated by a distance d configured so as to generate a plasma by capacitive coupling between the plate and the lateral wall, the plasma is thus generated in a localised manner in the vicinity of the substrate with a low ion flux.

### TECHNICAL FIELD OF THE INVENTION

The present invention relates to the field of plasma deposition reactors. It finds a particularly advantageous application in the field of thin layer deposition, and more particularly of thin layer with controlled thickness, for example for the manufacture of microelectronic devices.

### PRIOR ART

The atomic layer deposition (commonly referred to as ALD) methods are widely used to deposit thin layers, for example at thicknesses less than or equal to 100 nm, on 2D or 3D substrates. In general, the ALD deposition is a cyclic method comprising two main steps:
an injection of a precursor, typically a metal precursor,
an injection of another precursor, typically a reagent such as an oxygen or nitrogen-based reagent.

These steps are self-limiting, which allows depositing conformal and uniform layers on the substrate. The energy required for the reaction of the precursors can typically be provided by temperature (this is referred to as thermal ALD). This energy can be provided by using plasma enhancement (commonly referred to as PEALD, for Plasma Enhanced ALD) to improve the surface reactivity. This allows in particular reducing the working temperature, typically to temperatures less than or equal to 250° C.

The industrial PEALD reactors mainly use capacitively coupled or inductively coupled plasma sources (respectively commonly referred to as CCP, for Capacitively Coupled Plasma, and ICP, for Inductively Coupled Plasma). These reactors conventionally comprise a reaction chamber 10′, a gas precursor inlet 12′ configured to supply gas precursors into the chamber 10′, and a pumping module 13′ of the chamber 10′. In a CCP reactor 1′, for example illustrated in FIG. 1A, the plasma is generated 3 typically at pressures in the range of a few Torr between two electrodes 110′, 18′ with a radio frequency (RF) power device 16′. The electrodes 110′, 18′ are disposed in parallel facing each other and the substrate is deposited therebetween, an electrode 110′ being the plate connected to the ground 110′ carrying the substrate 2. In conventional CCP technologies, the ion bombardment on the plate is however significant. Grids can be added in the inter-electrode space to limit this ion bombardment. In an ICP reactor 1′, for example illustrated in FIG. 1B, the plasma is generated 3, typically at pressures in the range of 100 mTorr and in a remote manner by a source 15′, comprising an RF power device 16′, then is brought into the reaction chamber 10′ to the substrate 2 by diffusion. The ion bombardment is thus limited.

Indeed, the ion bombardment can generate point or extended defects, such as implantations, atom displacements, compressive stress in the growing layer, or even its sputtering.

However, the ion bombardment can be beneficial to modulate the surface reactivity and improve the deposition properties such as density, morphology, stress, conformity in particular on a 3D substrate, provided that the energy of this bombardment and the ion density thereof are controlled. To this end, some recently developed reactors use ICP plasmas to which an additional RF power has been added at the substrate holder, to allow the extraction of ions from the remote plasma with a controlled incident energy when they arrive in the vicinity of the substrate. In practice, the materials produced in these reactors are mainly oxides or nitrides, the physicochemical properties of which can be optionally modulated by an additional bias allowing extracting ions from the plasma so that they assist the growth mechanisms. Obtaining other materials remains limited.

An object of the present invention is therefore to propose an improved plasma-enhanced deposition reactor.

The other objects, features and advantages of the present invention will become apparent upon examining the following description and the appended drawings. It should be understood that other advantages could be incorporated.

### SUMMARY OF THE INVENTION

In order to achieve this objective, according to a first aspect, a plasma-enhanced deposition reactor is provided comprising:
a reaction chamber delimited by walls and comprising an electrically conductive plate having an upper face intended to receive a substrate,
a gas precursor inlet configured to supply gas precursors into the reaction chamber,
a pumping module of the reaction chamber,
a power source configured to apply a radio frequency power to the plate and generate the plasma.

A lateral wall of the reaction chamber is at least partially non-parallel to the upper face of the plate and is electrically conductive. The upper face of the plate and the lateral wall are separated by a distance configured so as to generate a plasma by capacitive coupling between the plate and the lateral wall.

The radio frequency power applied to the plate and the distance between the plate and the lateral wall allow generating the plasma by capacitive coupling between these two elements. The plasma thus locally generated in the vicinity of the substrate leads, thanks to the non-parallel configuration of the two electrodes, to an energy and an ion density which are than for a conventional CCP reactor, and finely adjustable, in particular according to the RF power and pressure conditions. Thus, this greatly limits the damage to the substrate caused by the ion bombardment. This lower ion flux is further more finely controllable relative to an ICP reactor with substrate bias, which allows achieving a better compromise between damages induced to the substrate and efficiency of ion bombardment. Finally, this reactor allows for the depositions of chemistry and microstructure layers which are more varied than a conventional ICP reactor with or without substrate polarization.

According to a second aspect, a method is provided for generating a plasma by capacitive coupling in a reactor comprising:
The provision of a reactor according to the first aspect,
A supply of gas for forming the plasma in the reaction chamber of the reactor,
The generation of a plasma by capacitive coupling between the plate and the lateral wall, the plate and the lateral wall being spaced apart by a distance d capable of generating a plasma by capacitive coupling between the plate and the lateral wall, d being the shortest distance between the plate and the lateral wall, the generation of the plasma comprising applying a radio frequency power to the plate.

### BRIEF DESCRIPTION OF THE FIGURES

The aims, objects, as well as the features and advantages of the invention will appear better from the detailed description of an embodiment of the latter which is illustrated by the following appended drawings, wherein:

FIG. 1A shows a sectional view of a CCP reactor according to an example of the prior art.

FIG. 1B shows a sectional view of an ICP reactor according to an example of the prior art.

FIG. 2 shows a sectional view of the plasma reactor according to an exemplary embodiment, in which the lateral wall is of conical geometry.

FIG. 3 shows a sectional view of the plasma reactor according to another exemplary embodiment, in which the lateral wall is of hemispherical geometry.

FIG. 4 shows a sectional view of the plasma reactor according to another exemplary embodiment, coupled to an ICP source.

FIG. 5 shows a sectional view of the plasma reactor illustrated in FIG. 2, equipped with an ellipsometer.

FIGS. 6A to 6D and 7A to 7C show graphs of ion flux generated by the plasma according to the plasma parameters, respectively at constant power and pressure. The drawings are given as examples and do not limit the invention. They form schematic representations of principle intended to facilitate understanding of the invention and are not necessarily plotted to the scale of practical applications. In particular, the relative dimensions of the substrate and the reactor are not representative of reality.

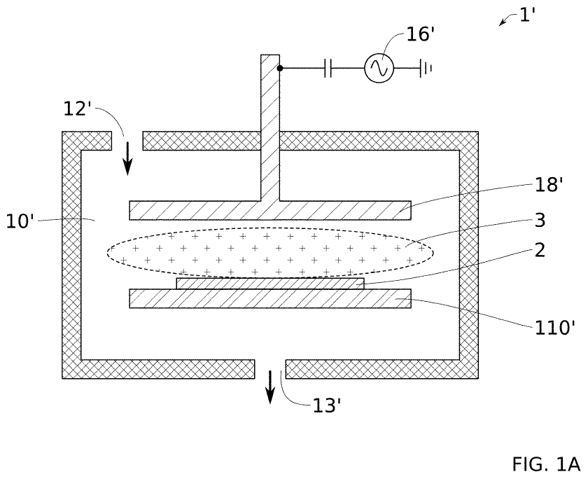

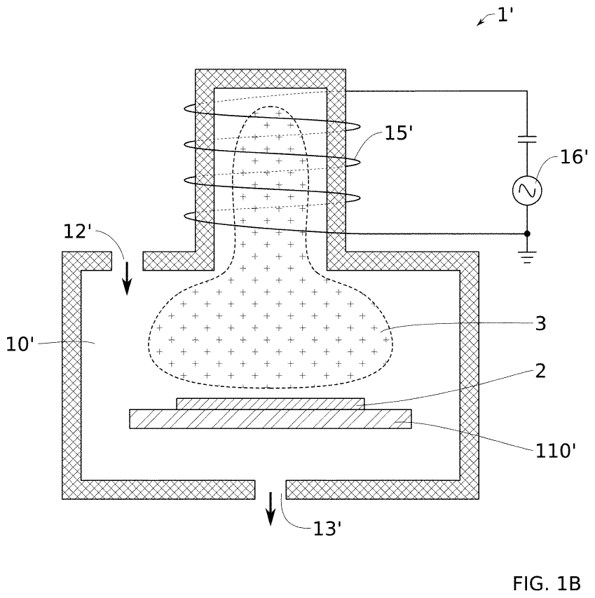

### DETAILED DESCRIPTION OF THE INVENTION

Before beginning a detailed review of embodiments of the invention, optional features are set out below that may optionally be used in combination or alternatively for each of the aspects of the invention.

According to one example, the reactor is a plasma-enhanced atomic layer deposition reactor.

According to one example, the plate is biased to ground.

According to one example, the reactor is configured to generate a plasma having an ion density substantially less than or equal to 10¹⁴ ions·cm⁻²·s⁻¹. This low-density plasma, located in the vicinity of the substrate, allows taking advantage more finely from the ion bombardment.

According to one example, the distance, and for example the minimum distance, between the upper face of the plate and the lateral wall is comprised between 5 cm and 15 cm, preferably between 5 cm and 12 cm. This distance range allowing the self-maintenance of the discharge is dictated by Paschen's law, a function of the pressure P in the reactor, and the minimum average voltage Uₘᵢₙ of the RF bias: Uₘᵢₙ=P·d. This allows obtaining an ion density≤10¹⁴ ions·cm⁻²·s⁻¹ for a very low-density plasma, further facilitating the adjustment of the plasma characteristics. This also allows obtaining the low-density plasma without excessively reducing the pressure in the reaction chamber, for pressures in the range of mTorr to a few hundred mTorr, for example 200 mTorr.

According to one example, the distance d is proportional, and preferably equal, to the ratio of U/P, P being the pressure in the reactor, and U the average voltage of the radio frequency bias applied to the plate, U being greater than or equal to a value Uₘᵢₙ of minimum average voltage of radio frequency self-bias.

According to one example, the lateral wall is at least partially disposed perpendicularly relative to the main extension plane of the upper face of the plate. The lateral wall is thus substantially vertical.

According to one example, the lateral wall is at least partially disposed obliquely relative to the main extension plane of the upper face of the plate. Edge effects are thus avoided and the field lines on the substrate are attenuated relative to a vertical wall.

According to one example, the lateral wall is disposed relative to the main extension plane of the upper face of the plate, so as to form an angle comprised between 15° and 85°, preferably between 30° and 80°. According to one example, and in particular when the lateral wall has a dome shape, the tangent of the lateral wall defines an angle, relative to the main extension plane of the upper face of the plate, comprised between 15° and 85°, preferably between 30° and 80°. The tangent of the lateral wall may be the tangent to a point of the lateral wall located in the main extension plane of the upper face of the plate.

According to one example, the electrically conductive lateral wall is at least partially disposed above the plate, projecting along a vertical plane, or substantially perpendicular to the upper face of the plate.

According to one example, the lateral wall has a symmetry of revolution about a direction perpendicular and substantially centred relative to the upper face of the plate. This symmetry allows the plasma to be ignited over the entire surface of the upper face. The plasma is therefore more homogeneous.

According to one example, the lateral wall does not have a symmetry of revolution about a direction perpendicular and substantially centred relative to the upper face of the plate. For example, it may be provided that the conductive lateral wall only partially surrounds the plate, projecting in a plane parallel to the main extension plane of the upper face of the plate.

According to one example, the lateral wall at least partially forms a cone above the plate, preferably the lateral wall has a conical geometry with an axis of revolution substantially centred relative to the plate.

According to one example, the lateral wall at least partially forms a dome above the plate, preferably the lateral wall at least partially has a hemispherical geometry, preferably substantially centred relative to the plate.

According to one example, the reactor is configured such that plasma is generated only in the reaction chamber by the power applied to the substrate holder by the power source. Thus, the reactor is of a simplified configuration, and therefore less expensive than that of a conventional PEALD ICP reactor.

According to one example, the reactor is configured such that the plasma is generated between two electrodes only and the reactor is configured such that the plate constitutes one of the two electrodes. For comparison, in an ICP reactor, the plasma is generated only by a coil supplied with an RF power.

According to one example, the reactor is free of an additional source of the ICP plasma type.

According to one example, the plate is not configured to be adjusted in height in the reaction chamber. The configuration of the reactor is thus further simplified.

According to one example, the reactor further comprises an inductively coupled plasma source remote from the reaction chamber. The reactor is thus a multimode reactor allowing a deposition enhanced by ICP plasma and/or by the plasma generated between the plate and the lateral wall, as required. The reactor thus allows carrying out different deposition methods as required.

When the reactor further comprises an inductively coupled plasma source remote from the reaction chamber, the reactor can thus comprise two independent plasma sources that can be used as desired: the power source for the CCP coupling and the inductively coupled plasma source for the ICP coupling. The bias powers applied by these two sources can be adjusted independently.

According to one example, the plate is not configured to be adjusted in height in the reaction chamber.

According to one example, the plate is configured to be adjusted in height in the reaction chamber. Thus, the distance d can be adjusted by the height of the plate, for example for different values of bias pressure or voltage, as required. The reactor therefore gains in versatility. When the reactor further comprises an inductively coupled plasma source remote from the reaction chamber, the height adjustment of the plate further allows adjusting the distance d between the plate and the lateral wall, which is particularly advantageous for modulating the properties of the plasma in the vicinity of the substrate. It is thus possible to decouple or couple the two plasmas of the CCP and ICP type as required.

According to one example, the gas precursor inlet and the pumping module are configured to maintain a pressure which is substantially comprised between 5 and 200 mTorr, preferably comprised between 5 mTorr and 100 mTorr, preferably comprised between 5 mTorr and 80 mTorr in the reaction chamber, at least when the plasma is generated. These pressures correspond to a high secondary vacuum.

According to one example, the gas precursor inlet and the pumping module are configured to maintain a pressure which is substantially less than or equal to 200 mTorr, preferably 100 mTorr in the reaction, chamber, at least when the plasma is generated.

According to one example, the gas precursor inlet and the pumping module are configured to maintain a pressure which is substantially greater than or equal to 10 mTorr in the reaction chamber, at least when the plasma is generated, preferably greater than or equal to 15 mTorr.

According to one example, the power source is configured to apply the radio frequency power with a frequency comprised between 2 and 100 MHz, when the plasma is generated by capacitive coupling between the plate and the lateral wall.

According to one example, the power source (for CCP coupling) is configured to apply a radio frequency power with a strictly positive power and less than or equal to 100 W, when the plasma is generated by capacitive coupling between the plate and the lateral wall. The inductively coupled plasma source remote from the reaction chamber can be configured to apply a radio frequency power with a non-zero power in absolute value which is comprised between 0 and 300 W.

The above parameters allow obtaining the following characteristics of ion flux of the plasma at the plate by capacitive coupling:
power density: 0.05 to 0.5 W/cm²,
ion flux: 10¹² to 10¹⁴ ions/(cm²·s)
ion energy: 0 to 300 eV.

According to one example, the power source comprises an attenuator configured to limit the power of the radio frequency bias of the plasma generated by capacitive coupling.

According to one example, the supply of gas for the formation of the plasma, in the reaction chamber of the reactor, is at least partially performed before the generation of a plasma by capacitive coupling, and preferably continues during the generation of the plasma.

According to one example, the plasma generation further comprises an adjustment of at least two plasma parameters, these parameters comprising the distance d, the pressure P in the reactor, the average voltage U of the radio frequency bias applied to the plate, such that:
d is proportional to, and preferably equal to, the ratio of U/P,
U is greater than or equal to a value Uₘᵢₙ of minimum average self-bias voltage.

According to one example, the plate of the reactor being configured to be adjusted in height in the reaction chamber, the plasma generation comprises an adjustment of the distance d by a height displacement of the plate, so as to reach a distance d allowing the generation of the plasma. It is thus possible to be positioned at a distance not allowing the generation of the plasma, and to displace the plate until a plasma is observed.

According to one example, during the generation of the plasma, the pressure in the reaction chamber is substantially comprised between 5 and 200 mTorr, preferably comprised between 5 mTorr and 100 mTorr. For example, the precursor supply can be configured to reach this pressure prior to the plasma generation. The gas precursor supply and the pumping module may be configured to maintain this pressure.

According to one example, a non-zero radio frequency power of less than or equal to 100 W is applied to the plate.

According to one example, the adjustment of the plasma parameters is carried out during and/or after application of the radio frequency power.

According to one example, the method may comprise providing a substrate having an exposed surface in the plasma reactor, and placing it on the upper face of the plate. The method may comprise the treatment, for example a deposition, on the exposed surface of the substrate, during the generation of the plasma.

In the following description, the term “over” does not necessarily mean “directly over”. Thus, when it is indicated that a part or a member A bears “on” a part or a member B, this does not mean that the parts or members A and B are necessarily in direct contact with the other. These parts or members A and B can either be in direct contact or bear on one another through one or more other part(s). The same applies for other expressions such as the expression “A acts on B” which could mean “A acts directly on B” or “A acts on B through one or more other part(s)”.

In the present patent application, the term movable corresponds to a rotational movement or to a translational movement or to a combination of movements, for example the combination of a rotation and a translation.

In the detailed following description which, use may be made of terms such as “horizontal”, “vertical”, “longitudinal”, “transverse”, “upper”, “lower”, “up”, “down”, “front”, “rear”, “inner”, “outer”. These terms must be interpreted relatively in relation to the normal operating position of the reactor. For example, the concepts “horizontal” and “longitudinal” correspond to the main direction of extension of the upper face of the plate.

A reference whose longitudinal or right/left direction corresponds to the x axis will also be used, the transverse or rear/front direction corresponds to the y axis and the vertical or down/up direction corresponds to the z axis.

The term “microelectronic device” means any type of device made with the microelectronic means. These devices include, in particular in addition to devices for purely electronic purposes, micromechanical or electromechanical devices (MEMS, NEMS, etc.) as well as optical or optoelectronic devices (MOEMS, LEDs, etc.).

This may be a device intended to ensure an electronic, optical, mechanical function, etc. It may also be an intermediate product intended only for the production of another microelectronic device.

A parameter “substantially equal to/greater than/less than” a given value means that this parameter is equal to/greater than/less than the given value, plus or minus 10%, close to this value. A parameter “substantially comprised between” two given values means that this parameter is at least equal to the smallest given value, plus or minus 10%, close to this value, and at most equal to the largest given value, plus or minus 10%, close to this value.

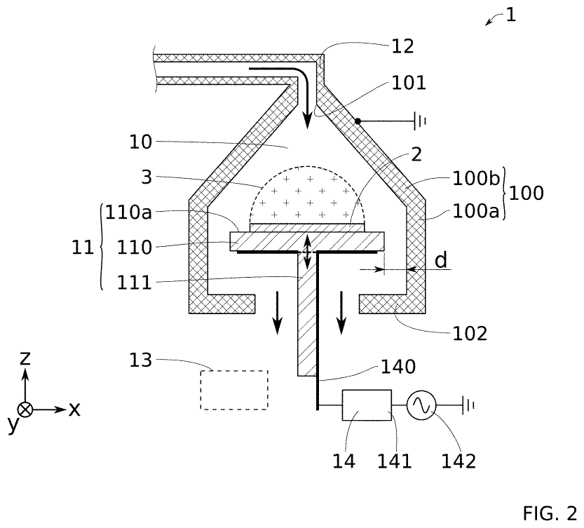

The plasma-enhanced deposition reactor 1 is now described according to several exemplary embodiments with reference to FIGS. 2 to 5. The reactor 1 is more particularly intended for plasma-enhanced atomic layer deposition.

The reactor 1 comprises a reaction chamber 10 intended to accommodate a substrate 2 and in which the deposition is intended to be carried out. This chamber 10 is delimited by one or more lateral walls 100, an upper wall 101 and a lower wall 102.

In order to perform the deposition of a layer on the substrate 2, the reactor 1 comprises means for the inlet and discharge of gas precursor(s) and/or gaseous species for the formation of the plasma. The reactor 1 comprises a gas precursor inlet 12 configured to supply gas precursors into the reaction chamber 10, as illustrated by the arrow at the top of the reactor in FIGS. 2 to 5. The gas precursor inlet 12 can further be configured to introduce gases into the chamber 10 for the plasma formation, for example rare gases such as helium or argon. The reactor 1 further comprises a pumping module 13 of the chamber 10. The pumping module 13 allows discharging the gaseous species present in the chamber, as illustrated by the two arrows at the bottom of the reactor in FIGS. 2 to 5. These species can in particular be discharged between different ALD deposition cycles. The pumping module 13 also allows, with the inlet 12, maintaining a given pressure inside the chamber 10, typically lower than the atmospheric pressure.

The substrate 2 is received in the reaction chamber 10 by a sample holder 11. The sample holder may comprise a plate 110 configured to receive the substrate 2, connected to an arm 111. The plate 110 may in particular have a planar upper face 110a supporting the substrate 2. The upper face 110a is for example substantially horizontal. It should be noted that the plate 110 can have other inclined faces, for example on the edges or a rounded lower face.

The reactor 1 is configured such that a plasma is generated by capacitive coupling between the upper face 110a of the plate 110 and the lateral wall 100, biased to ground as illustrated in FIGS. 2 to 5. For this, the plate 110 is electrically conductive. The plate 110 may be at least partially formed of an electrically conductive material. The lateral wall 100 is at least partially electrically conductive. The lateral wall 100 may be at least partially formed of an electrically conductive material. The reactor 1 further comprises a power source 14 configured to apply radio frequency power to the plate 110. The power source 14 may for example comprise a radio frequency power generator 142 connected to a member 140 for transmitting the radio frequency to the plate 110.

This power source 14 may comprise a regulation device 141 and allows inducing an RF voltage, also called self-bias voltage, on the plate 110 to generate the CCP plasma. Preferably, this regulation device 141 comprises an automatic adaptation unit (known as an auto match unit) which adapts the impedance of the plasma in the chamber 10 to that of the radio frequency power generator 142 so as to minimise the reflected power and allow the self-sustaining of the discharge. This power source 14 is configured to generate the plasma and allow the self-bias of the plate 110. Indeed, the plasma is supplied with power, and the adaptation unit (or equivalently a tuning box) adapts the impedance to minimise the reflected power and allow the self-maintenance of the discharge. The plasma is an electrical discharge having its own impedance depending on its degree of ionisation and the chemistry of the gases, as well as the geometric parameters of the reactor and the electrical power supply. The self-bias voltage can typically be from 50 V to 300 V for a power ranging from 10 W to 100 W, in particular in a reactor receiving substrates with a maximum diameter of 200 mm. The regulation device 141 can in particular comprise an attenuator configured to limit the power of the generator 142.

The lateral wall 100 is at least partially non-parallel to the upper face 110a of the plate 110. The upper face 110a of the plate 110 and the lateral wall 100, at least on its part non-parallel to the upper face of the plate, are separated by a distance d configured so as to generate a plasma by capacitive coupling between the plate 110 and the lateral wall 100, each acting as an electrode for generating the plasma. During the development of the invention, it was indeed highlighted that a non-parallel arrangement of the lateral wall 100 and the upper face 110a, coupled at a certain distance d, allow generating the plasma by capacitive coupling in the vicinity of the substrate 2, at a plasma generation zone 3.

The plasma is thus generated in a localised manner in the vicinity 3 of the substrate 2 with a much lower ion flux than for a conventional CCP reactor. This reactor 1 allows taking advantage of low-energy ion bombardment to improve the properties of the material (density, purity, crystal structure, internal stress). In addition, it opens up new avenues for developing methods concerning metals, oxides, nitrides and sulphides on 2D and 3D substrates, as well as selective surface and topographic deposition methods. This reactor 1 therefore allows carrying out depositions of varied nature, unlike existing reactors which are more limited. Indeed, this plasma generation mode allows making depositions of metal layers, in particular of transition metals and/or rare earths. Depositions of oxide, nitride and/or sulphide layers are also possible, in particular of transition metals and/or rare earths.

The distance d allowing the self-sustaining of the plasma discharge is dictated by Paschen's law, a function of the pressure P in the reactor, and of the minimum average RF self-bias voltage Uₘᵢₙ: Uₘᵢₙ=P·d. It is therefore understood that the distance d can vary depending on the pressure P in the chamber 10 and the minimum average voltage Uₘᵢₙ imposed by the power source 14.

This distance d is the shortest distance between the two electrodes formed by the plate 110 and the lateral wall 100. This distance can for example be the distance between one or both end edges of the plate 110 and the lateral wall 100, preferably between an upper face of the plate 110 and the lateral wall 100, and more particularly between one or both end edges of the upper face 110a of the plate 110 and the lateral wall 100. During the generation of the plasma, the plate 110 and the lateral wall 100 are spaced apart from each other by the distance d.

According to one example, the distance d between the upper face 110a of the plate 110 and the lateral wall 100 is comprised between 5 cm and 15 cm, preferably between 5 cm and 12 cm, and even more preferably between 5 and 8 cm. This distance range d is for example valid for a pressure P≤80 mTorr (with 1 mTorr=10⁻³ Torr and 1 Torr≈133.322 Pa), and Uₘᵢₙ (self-bias voltage) whose absolute value is substantially comprised between 0 V excluded and 300 V [0 V; 300 V], preferably between 50 V and 300 V [50 V; 300 V], and even more preferably between 100 V and 300 V. A sufficiently low ion density, substantially less than or equal to 10¹⁴ ions·cm⁻²·s⁻¹, can thus be obtained.

For the deposition of a layer by capacitive coupling according to the invention, the pressures are in the range of mTorr to a few hundred mTorr, for example 200 mTorr. The typically applied radio frequency power is less than or equal to 100 W, this power being non-zero. The parameters of pressure, self-bias voltage and distance are interdependent to obtain the generation of a plasma by capacitive coupling. As will be described in more detail later, it is possible in the reactor 1 that d is set, and that the self-bias voltage and the pressure are adjusted in corresponding ranges above. Alternatively, the distance d can be adjustable for example with means for adjusting the height of the plate 110, as described later.

It should be noted that the type of gas can have an influence on Paschen's law. These data are tabulated and known to the person skilled in the art, as for example described for argon in C. Torres, P. G. Reyes, F. Castillo, H. Martinez, Journal of Physics: Conference Series; Bristol Vol. 370, No. 1, (June 2012). The person skilled in the art will therefore be able to adapt these parameters, for example by adjusting the self-bias voltage and the pressure, d being set, or even in addition by adjusting the distance d, in particular in the aforementioned ranges.

In order to generate the plasma, the electrically conductive lateral wall 100 may be at least partially disposed above the plate 110, projecting from said wall on a plane perpendicular to the upper face 110a of the plate 110. It is therefore understood that at least one portion of the wall 100 is disposed opposite to the upper face of the plate, such that the plasma by capacitive coupling can be generated between the lateral wall 100 and the upper face 110a of the plate 110, on which the substrate 2 is placed.

According to one example, the reaction chamber 10 and more particularly the lateral wall 100 has a symmetry of revolution about a direction parallel to the z axis and substantially centred relative to the upper face 110a of the plate 110. This symmetry allows the plasma to be ignited over the entire surface of the upper face 110a of the plate 110. As soon as the plasma is ignited, it propagates over the entire lower electrode (the upper face 110a of the plate 110). The plasma is therefore more homogeneous.

According to one example, the lateral wall 100 is disposed vertically relative to the main extension plane (x, y) of the upper face 110a of the plate 110. A vertical wall, however, generates very tight field lines on the edges of the substrate, and therefore a more localised (and therefore more energetic) plasma. A more localised plasma can generate breakdown phenomena at the edges of the substrate and therefore edge effects.

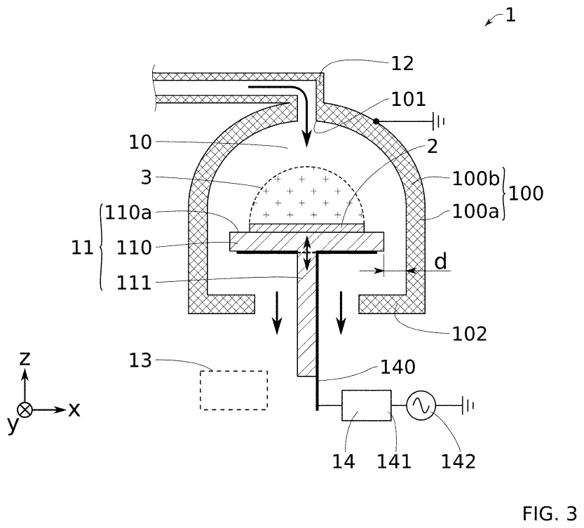

In order to limit this, as illustrated in FIGS. 2 and 3, the lateral wall 100 is preferably at least partially disposed obliquely relative to the main extension plane (x, y) of the upper face 110a of the plate 110. Equivalently, the lateral wall is disposed neither parallel nor perpendicular to the main extension plane (x, y) of the upper face 110a. This oblique arrangement allows in particular improving the obtained plasma by limiting the edge effects. The generated plasma is thus made more homogeneous for a better layer deposition.

The lateral wall 100 can comprise several portions 100a, 100b. A first portion 100a can be disposed substantially perpendicular to the main extension plane (x, y) of the upper face 110a. A second portion 100b may be disposed obliquely relative to the main extension plane (x, y) of the upper face 110a of the plate 110. Hereinafter, it is considered, without limitation, that the portion 100b of the lateral wall is disposed obliquely relative to the plane (x, y).

As for example illustrated in FIG. 2, the second portion 100b of the lateral wall 100 may have a conical geometry above the plate 110. This geometry may more particularly be selected depending on the distance d. The portion 100b may for example be in the form of a cone truncated by the upper wall 101. A truncated cone geometry allows the lateral wall not to form a hollow in which the species generated by the plasma could be accumulated. Preferably, the second portion 100b has a conical geometry with an axis of revolution which is substantially centred relative to the plate 110.

As illustrated for example in FIG. 3, the second portion 100b of the lateral wall 100 can form a dome above the plate 110. The portion 100b can for example be in the form of a half-sphere above the plate 110. Again, this geometry can more particularly be selected depending on the distance d. A dome-shaped geometry, and more particularly a hemispherical geometry, allows having a smaller chamber volume (therefore fewer consumed reagents, a chamber that is easier to pump, and limiting the dead volume in the chamber. Preferably, the second portion 100b has a hemispherical geometry, preferably substantially centred relative to the plate 110. The dome may be truncated by the upper wall 101. Alternatively, the lateral wall 100 may form a non-truncated dome.

It is understood, for example with reference to the dome geometry described above, that the lateral wall 100 may extend so as to form all or part of the upper wall 101.

According to one example, the plate 110 may be non-adjustable in height in the chamber 10. Equivalently, the plate 110 may be non-movable at least in the vertical direction z in the chamber 10. However, it may be provided that the plate 110 is configured to be movable, for example in rotation, at the fixed height of the chamber 10, for example to improve the uniformity of the deposition. This rotation can be about the axis of the arm 111 thereof. The plate 110 can alternatively be completely fixed in the chamber 10. In particular when the plate 110 is not adjustable in height, the geometry of the lateral wall 110 can be adapted relative to the sample holder to obtain the distance d allowing the generation of the plasma. The reactor 1 can thus be of simplified configuration, and therefore less expensive.

According to another example, the plate 110 can be adjustable in height in the chamber 10, as illustrated by the double vertical arrow in FIGS. 2 to 5. Equivalently, the plate 110 can be movable at least in the vertical direction z in the chamber 10. Thus, the distance d can be adjusted by the height of the plate 110, for example for different values of pressure or minimum voltage Uₘᵢₙ, as required. The properties of the plasma can further be modulated by adjusting the height of the plate 110 while ensuring that the plasma 3 is not extinguished. The height adjustment of the plate 110 can also be particularly advantageous when the reactor 1 comprises an additional plasma source, as described in more detail later. It can also be provided that the plate 110 is configured to be mobile, for example in rotation, for example to improve the uniformity of the deposition. This rotation can here again be about the axis of the arm 111 thereof.

The movement(s) of the plate 110 can for example be actuated by a motor, not shown in the figures.

As for example described in FIGS. 2 and 3, the reactor 1 can be configured to form only the plasma by capacitive coupling between the plate 110 and the lateral wall 100 in the reaction chamber. The plasma can in particular be generated between two electrodes only. The plate 110 may constitute one of the electrodes. The lateral wall 100 may constitute the other electrode. The reactor 1 may comprise only the generation by capacitive coupling between the plate 110 and the lateral wall 100 as a plasma source. The configuration of the reactor 1 is thus simplified, and therefore less expensive. It should be noted that the adjustment or not in height of the plate 110 is possible according to this example.

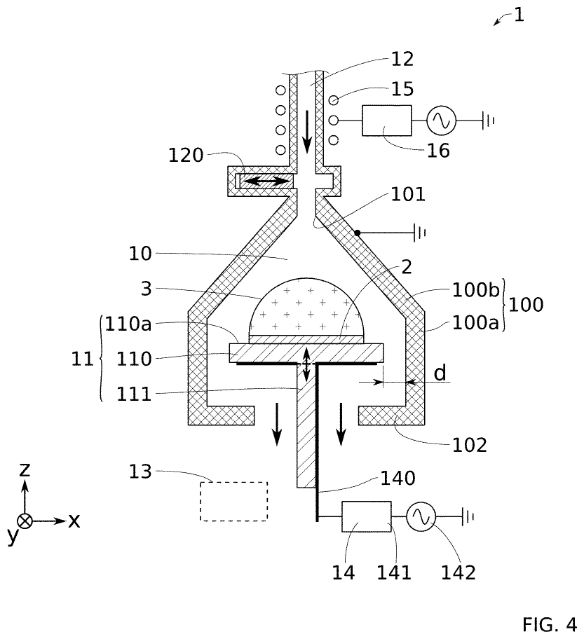

As illustrated for example in FIG. 4, the reactor 1 may comprise an inductively coupled plasma source 15 remote from the chamber 10. The reactor 1 may therefore be a multimode ICP and/or CCP reactor. Depending on the requirements, the plasma may be generated in ICP mode and/or in CCP mode. For this, the reactor 1 may comprise a radio frequency inductive source comprising a coil 15 powered by a radio frequency power generation device 16. The power source 14 and the inductive source 15, 16 are configured such that the RF power applied to the plate 110 is independent of the RF power of the inductive source.

When the reactor 1 operates in CCP mode, the generation of the plasma occurs by capacitive coupling between the upper face 110a of the plate 110 and the lateral wall 100 as previously described. When the reactor 1 operates in ICP mode, the plasma is generated by the inductively coupled plasma source 15. The power source 14 can then be used as a bias device configured to induce a bias voltage to the substrate 2 allowing the extraction of the ions from the remote plasma with a controlled incident energy at the moment when they arrive in the vicinity of the substrate 2.

The inlet of the gas precursors 12 can be disposed at the inductive source 15, 16. The inductive source 15, 16 can be isolated from the chamber 10 by a valve 120 having an open configuration for the passage of the plasma species from the source to the chamber 10, and a closed configuration for blocking these species. It should be noted that it is possible to provide for another inlet of gas precursors to be disposed directly at the chamber 10, without passing through the inductive source.

Preferably, when the reactor 1 can comprise an inductively coupled plasma source 15 remote from the chamber 10, the plate 110 is adjustable in height. Thus, depending on the distance d obtained between the plate 110 and the lateral wall 100, a plasma can be generated by the inductive source 15, 16 only, or by both the inductive source 15, 16 and the capacitive coupling between the plate 110 and the lateral wall 100. It should be noted that an adjustment or not in height of the plate 110 is possible according to this example.

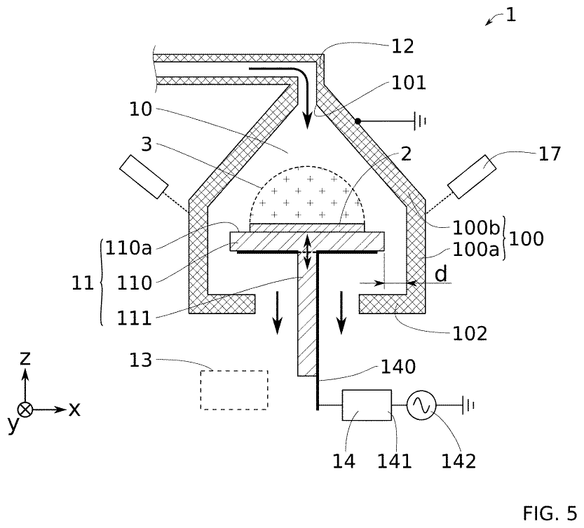

As illustrated for example in FIG. 5, the reactor 1 can further comprise a module 17 for determining the thickness of the deposited layer. This module 17 can for example comprise an ellipsometer coupled to the reactor 1, for example to the lateral wall 100 thereof. FIG. 5 is a representation of principle. In practice, the two points of intersection of the emitted and reflected rays intersect on the surface of the substrate where the growth takes place.

Examples of operating parameters of the reactor 1 are now described.

The RF power and pressure conditions in the chamber 10 allow finely adapting the characteristics of the ion flux of the plasma.

The gas precursor inlet 12 and the pumping module 13 can be configured to maintain a pressure substantially comprised between 5 and 200 mTorr, preferably comprised between 5 mTorr and 100 mTorr, preferably comprised between 5 mTorr and 80 mTorr in the reaction chamber 10.

The power source 14 can be configured to apply the radio frequency bias with a power less than or equal to 100 W.

The power source 14 can be configured to apply the radio frequency bias with a frequency comprised between 2 and 100 MHz when the plasma is generated by capacitive coupling.

It should be noted that when the reactor comprises an inductively coupled plasma source 15, and operates in ICP mode, the power source acting as a bias device configured to induce a bias voltage to the substrate 2 can operate at a higher power and/or at a frequency other than the range specified above.

These parameters in the ranges indicated above allow obtaining the following ion flux characteristics of the plasma generated by capacitive coupling, adapted for PEALD deposition:
power density: 0.05 to 0.5 W/cm²
ion flux: 10¹² to 10¹⁴ ions/(cm²·s)
ion energy: 0 to 300 eV (with 1 eV≈1.60218.10⁻¹⁹ J).

The following table describes examples of plasma generation parameters according to the invention, for an Argon plasma, without a remote ICP source. The distance d corresponding to these measurements is comprised between 5 and 6 cm.

TABLE 1

| Gaz | Ar | Ar | Ar | Ar | Ar | Ar | Ar | Ar | Ar | Ar |
|---|---|---|---|---|---|---|---|---|---|---|
| Flux (sccm or cm³ | 60 | 60 | 60 | 60 | 60 | 60 | 60 | 60 | 60 | 60 |
| standard/min) | | | | | | | | | | |
| Pressure | 7 | 7 | 7 | 7 | 7 | 7 | 7 | 7 | 7 | 7 |
| (mTorr) | | | | | | | | | | |
| Applied RF | 1 | 2 | 3 | 5 | 7 | 8 | 9 | 10 | 70 | 80 |
| Power (W) | | | | | | | | | | |
| Vdc probe(V) | 0 | 0 | 0 | 0 | 0 | 56 | 61 | 67 | 222 | 253 |
| Vdc flexal (V) | 0 | 0 | 0 | 0 | 0 | 56 | 62 | 68 | 233 | 241 |

The Vdc probe and flexal parameters give the self-bias voltage, corresponding to the impedance matching between the plasma and the reactor tuning box. Vdc probe given by a probe measurement (which allows determining the ion flux) and Vdc flexal is given directly by the reactor tuning box. The reactor is supplied with applied RF power and the self-bias voltage remains zero when the plasma does not ignite or self-sustain. In this case, all power is stored in the tuning box.

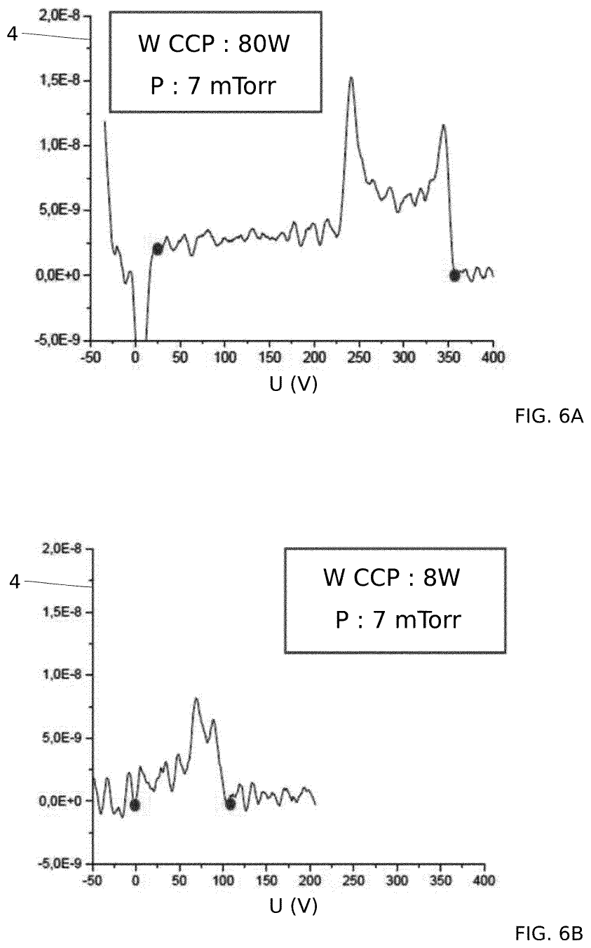

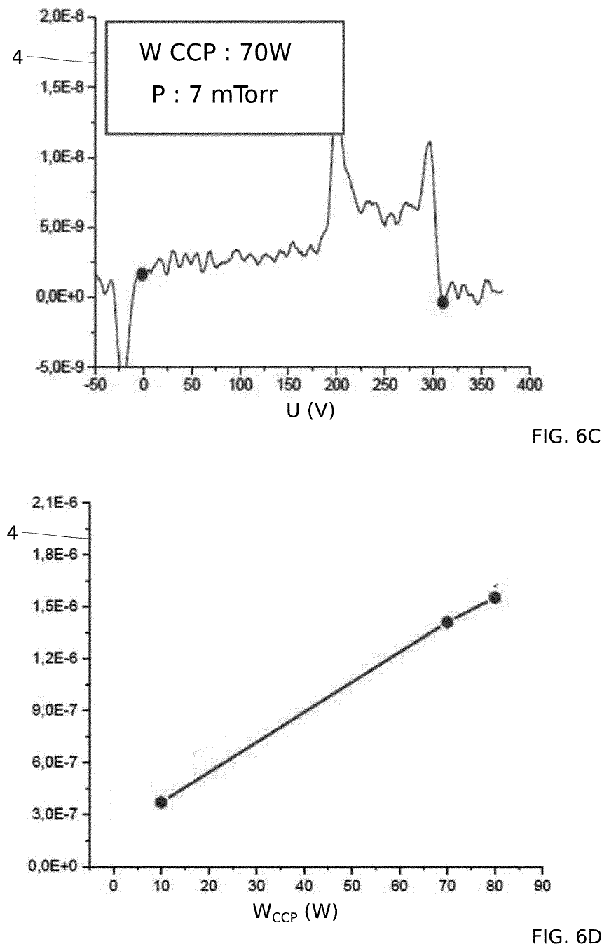

FIGS. 6A to 6D describe, for the example parameters of Table 1, the effect of the RF power W_{CCP} applied to the plate 110 on the generated ion flux 4 (in arbitrary units), at a constant pressure P, and depending on the self-bias voltage U.

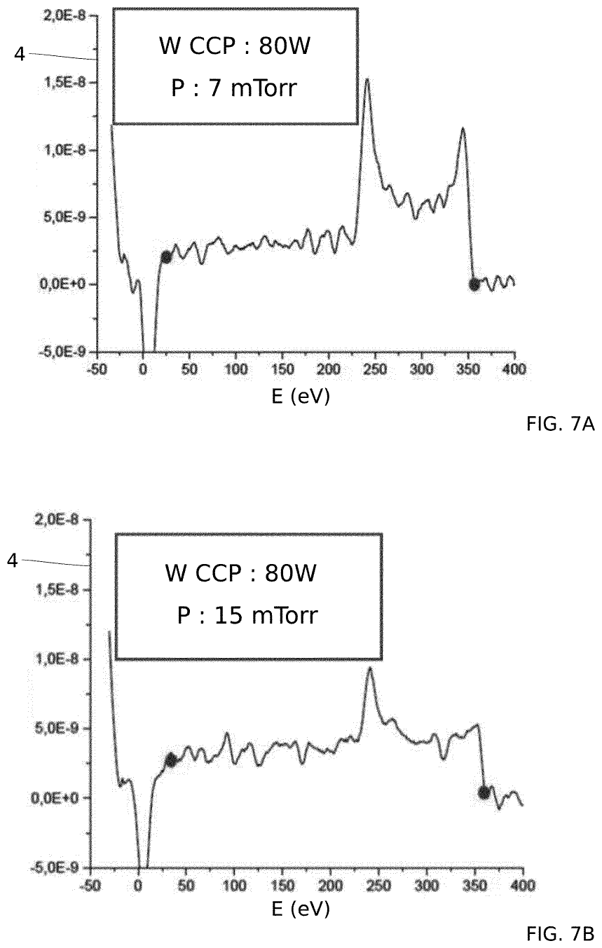

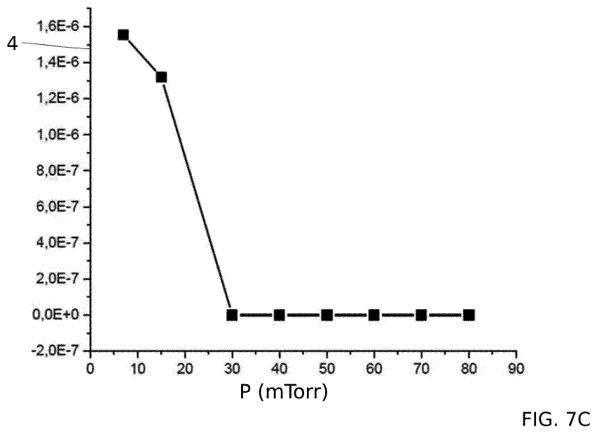

FIGS. 7A to 7C describe, for the example parameters of Table 1, the effect of the pressure P on the generated ion flow 4 (in arbitrary units), at constant RF W_{CCP} power applied to the plate 110, and depending on the self-bias voltage U, and of the ion energy E. In view of the preceding description, it is clear that the invention proposes an improved plasma-enhanced deposition reactor, in particular allowing gentler plasma enhancement than existing solutions, and therefore which generates fewer induced defects.

The invention is not limited to the previously-described embodiments and encompasses all of the embodiments covered by the invention. The present invention is not limited to the previously-described examples. Many other variants are possible, for example by combining previously-described features, without departing from the scope of the invention. In the illustrated examples, the inlet 12 has been shown at the upper face 101 of the reactor 1. Another arrangement, for example at the lateral wall 100, is possible. The same applies to the pumping module 13.

1. A plasma-enhanced deposition reactor comprising:
a reaction chamber delimited by walls and comprising an electrically conductive plate having an upper face intended to receive a substrate,
a gas precursor inlet configured to supply gas precursors into the reaction chamber,
a pumping module of the reaction chamber,
a power source configured to apply a radio frequency power to the plate and generate the plasma,
wherein a lateral wall of the reaction chamber is at least partially non-parallel to the upper face of the plate and is electrically conductive, the reactor being characterised in that said lateral wall is at least partly disposed above the plate, projecting from said wall on a plane perpendicular to the upper face of the plate, the plate is biased to ground, and in that the upper face of the plate and said lateral wall are separated by a distance d configured so as to generate a plasma by capacitive coupling between the plate and said lateral wall, d being the shortest distance between the plate and said lateral wall.

2. The reactor according to claim 1, wherein the distance d is proportional to the ratio of U/P, P being the pressure in the reactor, and U the average voltage of the radio frequency bias applied to the plate, U being greater than or equal to a value Uₘᵢₙ of minimum average voltage of radio frequency self-bias.

3. The reactor according to claim 1, wherein the distance d between the upper face of the plate and the lateral wall is comprised between 5 cm and 15 cm.

4. The reactor according to claim 1, wherein said lateral wall is at least partially disposed obliquely relative to the main extension plane of the upper face of the plat.

5. The reactor according to claim 4, wherein said lateral wall at least partially forms a cone above the plate.

6. The reactor according to claim 4, wherein the lateral wall at least partially forms a dome above the plate.

7. The reactor according to claim 1, configured such that the plasma is generated only in the reaction chamber.

8. The reactor according to claim 7, configured such that the plasma is generated between two electrodes only and the reactor is configured such that the plate constitutes one of the two electrodes.

9. The reactor according to claim 1, the reactor further comprising an inductively coupled plasma source remote from the reaction chamber.

10. The reactor according to claim 1, wherein the plate is not configured to be adjusted in height in the reaction chamber.

11. The reactor according to claim 1, wherein the plate is configured to be adjusted in height in the reaction chamber.

12. The reactor according to claim 1, wherein the gas precursor and the pumping module are configured to maintain a pressure which is substantially comprised between 5 and 200 mTorr.

13. The reactor according to claim 1, wherein the power source is configured to apply the radio frequency power with a frequency comprised between 2 and 100 MHz when the plasma is generated by capacitive coupling between the plate and the lateral wall.

14. The reactor according to claim 1, wherein the power source is configured to apply the radio frequency power with a power less than or equal to 100 W, when the plasma is generated by capacitive coupling between the plate and the lateral wall.

15. The reactor according to claim 1, wherein the power source comprises an attenuator configured to limit the power of the radio frequency bias.

16. A method for generating a plasma by capacitive coupling in a reactor comprising:
the provision of a reactor according to claim 1,
a supply of gas for forming the plasma in the reaction chamber of the reactor,
the generation of a plasma by capacitive coupling between the plate and the electrically conductive lateral wall, the plate and said lateral wall being spaced apart by a distance d capable of generating a plasma by capacitive coupling between the plate and the lateral wall, d being the shortest distance between the plate and said lateral wall, the generation of the plasma comprising applying a radio frequency power to the plate.

17. The method according to claim 16, wherein the generation of the plasma further comprises an adjustment of at least two plasma parameters, these parameters comprising the distance d, the pressure P in the reactor, the average voltage U of the radio frequency bias applied to the plate, such that:
d is proportional to the ratio of U/P,
U is greater than or equal to a value Uₘᵢₙ of minimum average voltage of radio frequency self-bias.

18. The method according to claim 16, wherein, the plate of the reactor being configured to be adjusted in height in the reaction chamber, the generation of the plasma comprises an adjustment of the distance d by a height displacement of the plate, so as to reach a distance d allowing the generation of the plasma.

19. The method according to claim 16, wherein, during the generation of the plasma, the pressure in the reaction chamber is substantially comprised between 5 and 200 mTorr.
